(19) United States
(12) Patent Application Publication
(10) Pub. No.: US 2005/0047227 A1
(43) Pub. Date: Mar. 3, 2005

(54) Semiconductor device and ID generator configured as semiconductor device

(75) Inventors: Kenichi Ohkubo, Katano-shi (JP); Atsushi Noda, Ogaki-shi (JP)

Correspondence Address: FISH & RICHARDSON PC, 225 FRANKLIN ST, BOSTON, MA, 02110, US

(73) Assignee: Sanyo Electric Co., Ltd., Osaka (JP)

(21) Appl. No.: 10/924,735

(22) Filed: Aug. 24, 2004

(30) Foreign Application Priority Data
Aug. 26, 2003 (JP) 2003-301526

(51) Int. Cl. G11C 29/00

(52) U.S. Cl. 365/200

(57) ABSTRACT

A semiconductor device that is difficult to reverse engineer. The semiconductor device includes a reconfigurable circuit having a circuit configuration that is switchable in accordance with circuit operation setting data. A non-volatile memory stores the circuit operation setting data. A register receives the circuit operation setting data from the non-volatile memory and provides the circuit operation setting data to the reconfigurable circuit when the semiconductor device is activated. Since the circuit configuration of the reconfigurable circuit is determined by the circuit operation setting data, the operation of the reconfigurable circuit cannot be analyzed when a peeling analysis is conducted on the semiconductor device.

### CROSS-REFERENCE TO RELATED APPLICATIONS

This application is based upon and claims the benefit of priority from prior Japanese Patent Application No. 2003-301526, filed on Aug. 26, 2003, the entire contents of which are incorporated herein by reference.

### BACKGROUND OF THE INVENTION

The present invention relates to a semiconductor device, and more particularly, to a semiconductor device which is difficult to reverse engineer and a semiconductor device functioning as an ID generator which generates an identification signal used for identifying whether an external unit attached to a main device is authentic or not.

Typically, a portable device such as a cellular phone is provided with a battery pack that is detachable from the main body. The battery pack has a battery for supplying power to the main body. If the battery deteriorates, the portable device is used continuously simply by replacing the battery pack.

While various improvements have been made for reducing the production costs of battery packs, the quality decrease of the battery packs associated with such improvements has been witnessed rather often. If a low-quality battery pack as such is used for a device, the device may not function properly or be damaged, for example, by the heat generated by the battery pack.

Accordingly, to identify if a battery pack has adequate quality in the prior art, for example, Japanese Laid-Open Patent Publication No. 2003-162986 describes the use of an identification signal to authenticate an external device, such as a battery pack, that is attached to a main device.

FIG. 1 is a schematic block diagram of a conventional authentication system 60 for identifying a battery pack (external unit) 62 detachably attached to a portable device (main device) 61.

The portable device 61 is provided with a microcomputer 63, which exchanges data with an exclusive LSI 64 mounted to the battery pack 62 and identifies the battery pack 62.

When the battery pack 62 is attached to the portable device 61, the microcomputer 63 activates an authentication processor 71 and generates an ID acquisition code (code sequence) for receiving from the battery pack 62 an identification signal (ID) to identify whether the battery pack 62 is appropriate.

The code is provided to an encryption processor 72 of the microcomputer 63. The encryption processor 72 performs a predetermined operation (encryption processing) based on the code and generates an identification signal for the portable device 61 (first identification signal). The code is also provided to an encryption processor 75 of an exclusive LSI 64 via a communicator 73 of the microcomputer 63 and a communicator 74 of the LSI 64. The encryption processor 75 performs a predetermined operation (encryption processing) based on the received code and generates an identification signal for the battery pack 62 (second identification signal). The second identification signal is transferred to the authentication processor 71 via the communicators 74 and 73.

The authentication processor 71 compares the first and second identification signals and determines whether or not the battery pack 62 is appropriate for the portable device 61.

For a typical LSI (semiconductor device), it is possible to analyze the entire circuit configuration of a package through a peeling analysis. Peeling analysis is conducted by removing the package mold to analyze contacts in wiring patterns of each layer. Upper wiring patterns are removed to analyze lower wiring patterns so as to ultimately perform the analysis at the transistor level.

Alternatively, signal analysis may be employed to completely analyze the circuit operation of a package. Signal analysis is conducted by removing the package mold and analyzing signals in the device in an active state by using a mechanical probe or an electronic probe using an electronic beam (EB). This enables thorough analysis of the circuit operation.

If such a peeling analysis is conducted on the exclusive LSI 64 to analyze its circuit configuration or if signal analysis is conducted to analyze its circuit operation (to conduct so-called reverse engineering), the retrieval of the identification signal is relatively easy. Accordingly, there is a high risk of encryption information leakage and confidentiality is not sufficient.

### SUMMARY OF THE INVENTION

The present invention provides a semiconductor device and ID generator which are difficult to reverse engineer.

One aspect of the present invention is a semiconductor device including a reconfigurable circuit having a circuit configuration that is switchable in accordance with circuit operation setting data. A non-volatile memory stores the circuit operation setting data. A register, connected to the non-volatile memory and the reconfigurable circuit, receives the circuit operation setting data when read from the non-volatile memory and provides the circuit operation setting data to the reconfigurable circuit.

A further aspect of the present invention is a semiconductor device including a plurality of signal wirings formed in a plurality of layers, respectively. A probe inhibiting wiring covers, among the plurality of signal wirings, at least a signal wiring that transmits a signal significant for analysis of operation of the semiconductor device.

Another aspect of the invention is an ID generator, configured as a semiconductor device, for generating an identification signal required to authenticate an external device attached to a main device. The ID generator includes a reconfigurable circuit configured to dynamically respond to circuit operation setting data and generate an identification signal in accordance with predetermined encryption processing. A non-volatile memory stores the circuit operation setting data. A register is connected to the non-volatile memory and the reconfigurable circuit for receiving the circuit operation setting data when read from the non-volatile memory and providing the circuit operation setting data to the reconfigurable circuit.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic block diagram showing a conventional authentication system;

FIG. 2 is a schematic block diagram showing a semiconductor device according to a preferred embodiment of the present invention;

FIG. 3 is a schematic block diagram showing a reconfigurable cell in the semiconductor device of FIG. 2;

FIG. 4(a) illustrates a wiring layout pattern of an inverter circuit configuring a register of the semiconductor device of FIG. 2;

FIG. 4(b) illustrates a layout pattern of the inverter circuit provided with a probe inhibiting wiring; and

FIG. 5 is a schematic block diagram showing an example in which the semiconductor device according to the preferred embodiment of the present invention is employed as an ID generator in an authentication system.

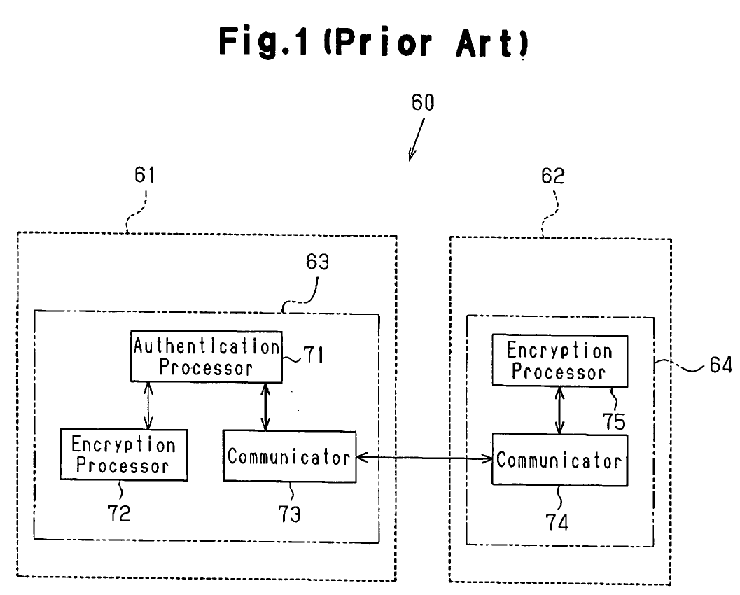

### DESCRIPTION OF THE PREFERRED EMBODIMENTS

In the drawings, like numerals are used for like elements throughout.

A semiconductor device 10 according to a preferred embodiment of the present invention will now be described with reference to the drawings.

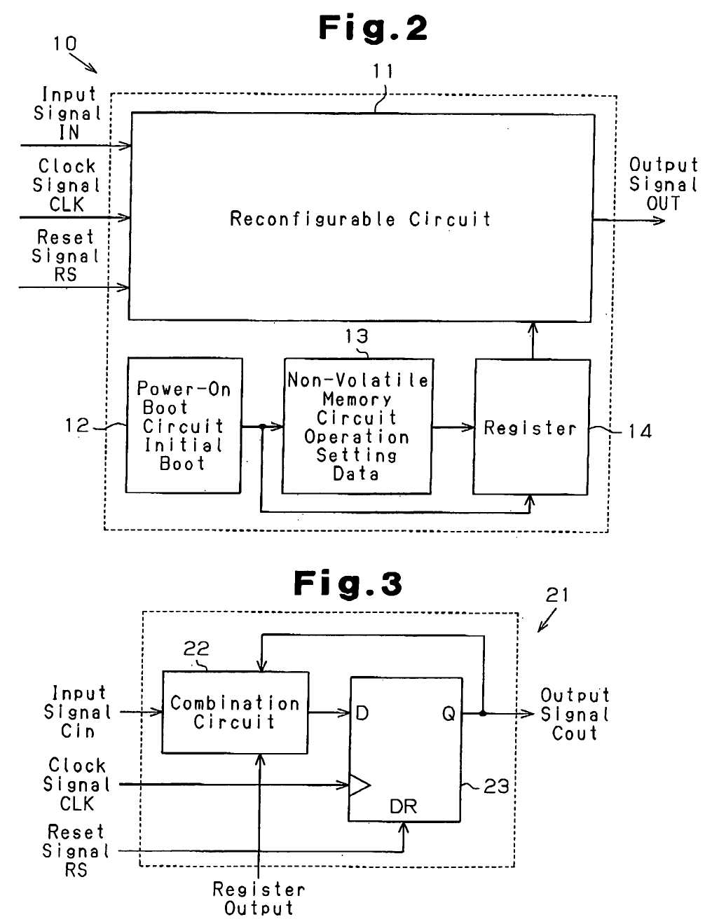

As shown in FIG. 2, the semiconductor device 10 includes a reconfigurable circuit 11, a power-on boot circuit (hereinafter referred to as “boot circuit”) 12, a non-volatile memory 13, and a register 14, all of which are formed on the same semiconductor substrate.

The reconfigurable circuit 11 includes a plurality of reconfigurable cells 21 (see FIG. 3), each of which is operation-controlled (programmed) individually. The reconfigurable circuit 11 switches circuit configurations in accordance with a combination logic set for each of the reconfigurable cells 21.

The non-volatile memory 13 stores circuit operation setting data, which is written beforehand, for setting a combination logic for each of the reconfigurable cells 21 in accordance with a function realized by the reconfigurable circuit 11. The circuit operation setting data is read from the non-volatile memory 13 when the boot circuit 12 performs an initial boot operation during activation of the device (semiconductor device 10). The circuit operation setting data is then loaded into the register 14 and subsequently provided from the register 14 to the reconfigurable circuit 11.

The reconfigurable circuit 11 receives the circuit operation setting data from the non-volatile memory 13 via the register 14 and switches the circuit configuration based on the circuit operation setting data in accordance with the function executed by the circuit 11. In this manner, the reconfigurable circuit 11 receives an input signal IN from an external device and generates an output signal OUT in accordance with the switched circuit configuration.

FIG. 3 is a schematic block diagram showing one of the reconfigurable cells 21 in the reconfigurable circuit 11. The reconfigurable cell 21 includes a programmable combination circuit 22, which realizes a combination logic, and a D-flip-flop (hereinafter to be referred to as “DFF”) 23, which functions as a holding circuit. The reconfigurable cell 21 is configured as a sequence circuit by the combination circuit 22 and the DFF 23.

The combination circuit 22 is configured as a logic module having a plurality of logic gates. The plurality of logic gates may include various types of logic gates, such as an inverter circuit, an AND circuit, and an OR circuit. The combination circuit 22 determines a combination logic (connection modes of the logic gates) based on the circuit operation setting data from the register 14 and performs an operation on an input signal Cin in accordance with an output signal Cout of the DFF 23. The combination circuit 22 provides the DFF 23 with the operation result as output data.

The DFF 23 latches the output data of the combination circuit 22 in accordance with a clock signal CLK and outputs the latched data as an output signal Cout while also feeding back the latched data to the combination circuit 22. The DFF 23 is reset by a reset signal RS provided to its reset input terminal (DR).

In the semiconductor device 10, the circuit configuration of the reconfigurable circuit 11 is determined only by the circuit operation setting data written beforehand in the non-volatile memory 13. Therefore, it is impossible to analyze the operation of the reconfigurable circuit 11 by conducting the peeling analysis. Further, it is also impossible to analyze the contents of the data written to the non-volatile memory 13 by conducting the peeling analysis. This configuration prevents the circuit operation of the reconfigurable circuit 11, or the circuit operation of the semiconductor device 10, from being analyzed, and thus makes reverse engineering difficult.

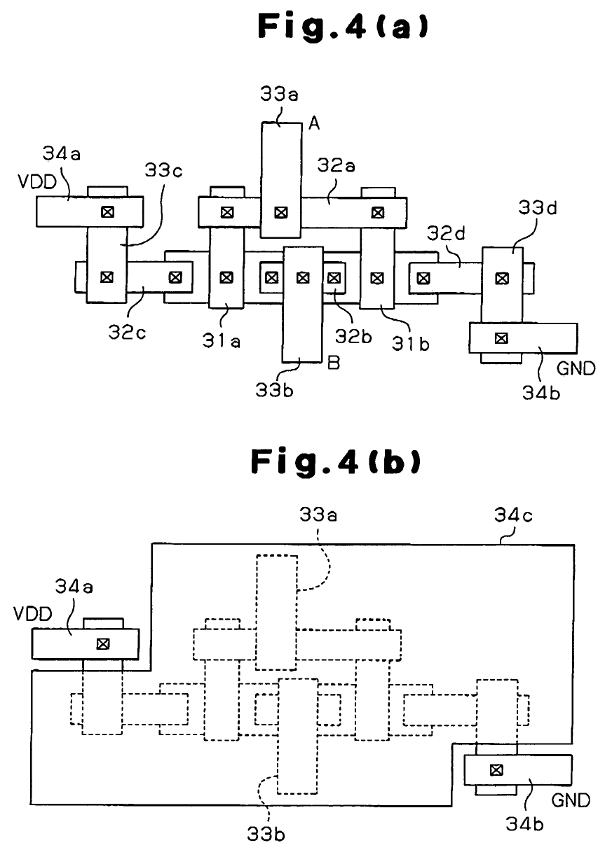

The structure of the register 14 in the semiconductor device 10 will now be described with reference to FIGS. 4(a) and 4(b).

FIG. 4(a) illustrates a layout pattern of one of a plurality of ring-connected inverter circuits, which configure the register 14. The inverter circuit is, for example, a CMOS inverter including an n-channel MOS transistor (hereinafter referred to as an “nMOS transistor”) and a p-channel MOS transistor (hereinafter referred to as a “pMOS transistor”) that are formed on a p-type substrate.

The inverter circuit has, for example, a three-layer aluminum wiring structure. The gate terminals of pMOS and nMOS transistors are connected to a first-layer wiring 32a by polycrystalline silicon gates 31a and 31b. The first-layer wiring 32a is connected to a second-layer wiring 33a. The drain terminals of the pMOS and nMOS transistors are connected to a first-layer wiring 32b. The first-layer wiring 32b is connected a second-layer wiring 33b.

The source terminal of the pMOS transistor is connected to a first-layer wiring 32c, which is connected to a third-layer wiring 34a via a second-layer wiring 33c. The third-layer wiring 34a is a power supply wiring supplied with power VDD. The source terminal of the nMOS transistor is connected to a first-layer wiring 32d, which is connected to a third-layer wiring 34b via a second-layer wiring 33d. The third-layer wiring 34b is a power supply wiring supplied with ground power GND.

The inverter circuit configured in this manner inverts an input signal A provided to the second-layer wiring 33a based on the supply of powers VDD and GND and outputs an inverted output signal B from the second-layer wiring 33b.

In the preferred embodiment, as shown in FIG. 4(b), the layout pattern of the inverter circuit having a three-layer wiring structure of FIG. 4(a), a third-layer wiring 34c is formed so as to cover at least the second-layer wiring 33a, which transmits the input signal A, and the second-layer wiring 33b, which transmits the output signal B. More specifically, the third-layer wiring 34c is formed by an uppermost layer wiring, which is in the same layer as the third-layer wirings 34a and 34b, which are respectively supplied with the powers VDD and GND. Further, the third-layer wiring covers all the wirings located in lower than the third-layer wirings 34a and 34b, which serve as power supply wirings.

In the layout pattern shown in FIG. 4(b), signal wirings (second-layer wirings 33a and 33b) transmitting the input signal A and output signal B in the inverter circuit are completely covered by the third-layer wiring 34c (probe inhibiting wiring), which is a layer located above the second-layer wirings 33a and 33b. For this reason, it is impossible to analyze the input signal A or the output signal B by probing the second-layer wiring 33a or 33b mechanically or with an electronic beam (EB).

If the third-layer wiring 34c is removed from the layout pattern of FIG. 4(b) to perform signal analysis on the input signal A and the output signal B, the third-layer wirings 34a and 34b, which serve as power supply wirings, are also removed together. This breaks the power supply line leading to the inverter circuit and erases the value held in the register 14, which is configured by the ring-connected inverter circuits. Thus, it is impossible to analyze signals in the register 14 in an active state.

Accordingly, in the semiconductor device 10 having the reconfigurable circuit 11 (see FIG. 2), even if the circuit operation setting data of the non-volatile memory 13 is loaded into the register 14, the register value is prevented from being read through signal analysis. Further, wirings in lower layers are covered by wirings of upper layers. This prevents the operation of the reconfigurable circuit 11 from being signal-analyzed. Consequently, the semiconductor device 10 is difficult to reverse engineer.

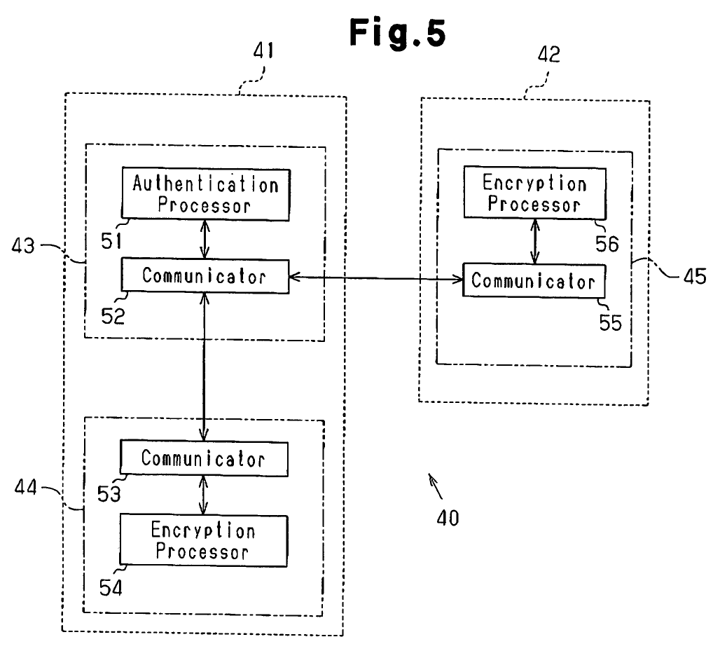

With reference to FIG. 5, an example in which the semiconductor device 10 is embodied as an ID generator mounted to an authentication system 40 will now be described. The authentication system 40 identifies a battery pack attached to a portable device such as a cellular phone.

The authentication system 40 includes a portable device (main body of a cellular phone) 41 and a battery pack (external device) 42 detachably attached to the portable device 41.

The portable device 41 includes a microcomputer 43, which functions as an authentication device for identifying whether the battery pack 42 attached to the portable device 41 is appropriate, and an exclusive LSI (hereinafter referred to as “first LSI”) 44, which functions as a first ID generator. The battery pack 42 includes a battery (not shown) and an exclusive LSI (hereinafter referred to as “second LSI”) 45, which functions as a second ID generator. The battery of the battery pack 42 is electrically connected with the portable device 41 through a power supply terminal (not shown).

The microcomputer 43 of the portable device 41 includes an authentication processor 51 and a communicator 52. The authentication processor 51 communicates data with the first LSI 44 of the portable device 41 and the second LSI 45 of the battery pack 42 in accordance with a predetermined communication protocol. Further, the authentication processor 51 performs authentication processing to identify whether or not the battery pack 42 is an appropriate one.

The first LSI 44 is a semiconductor device including a communicator 53 for communicating with the microcomputer 43 and an encryption processor 54 for generating an identification signal for the portable device 41 (first identification signal). This semiconductor device is configured by the semiconductor device 10 that includes the reconfigurable circuit 11. More specifically, circuit operation setting data causing the reconfigurable circuit 11 to function as the encryption processor 54 and the communicator 53 is written to the non-volatile memory 13 of the semiconductor device 10. Due to the circuit operation setting data, the semiconductor device 10 functions as the first LSI 44. The encryption processor 54 of the first LSI 44 receives from the authentication processor 51 data used to generate an identification signal. The encryption processor 54 then generates a first identification signal by performing a predetermined encryption process, which is in accordance with a predetermined encryption algorithm, on the received data.

The second LSI 45 is a semiconductor device including a communicator 55 for communicating with the microcomputer 43 and an encryption processor 56 for generating an identification signal for the battery pack 42 (second identification signal). This semiconductor device is configured by the semiconductor device 10 that includes the reconfigurable circuit 11. More specifically, circuit operation setting data causing the reconfigurable circuit 11 to function as the encryption processor 56 and the communicator 55 is written to the non-volatile memory 13 of the semiconductor device 10. Due to the circuit operation setting data, the semiconductor device 10 operates as the second LSI 45. The encryption processor 56 of the second LSI 45 receives from the authentication processor 51 data used to generate an identification signal. The encryption processor 56 then generates a second identification signal by performing a predetermined encryption process, which is in accordance with a predetermined encryption algorithm, on the received data.

The encryption processor 54 of the first LSI 44 and the encryption processor 56 of the second LSI 45 perform encryption processing in accordance with the same encryption algorithm and generate the same identification signal when provided with the same data from the authentication processor 51.

The authentication processor 51 compares the first identification signal generated by the encryption processor 54 of the first LSI 44 and the second identification signal generated by the encryption processor 56 of the second LSI 45. When the first and second identification signals match, the authentication processor 51 determines that the battery pack 42 is an appropriate one.

In the authentication system 40, the first and second LSIs 44 and 45, which generate identification signals required for performing authentication, are both configured by the semiconductor device 10 that includes the reconfigurable circuit 11. This improves the confidentiality of the encryption algorithm used for generating identification signals. In other words, even if a third party conducts a peeling analysis or signal analysis on the first and second LSIs 44 and 45, the third party is prevented from acquiring an identification signal. Thus, the system has an extremely high level of confidentiality.

The semiconductor device 10 of the preferred embodiment has the advantages described below.

(1) The semiconductor device 10 is provided with the reconfigurable circuit 11 including the reconfigurable cells 21, each of which is operation-controlled individually. The circuit operation of the reconfigurable circuit 11 is determined by the circuit operation setting data that is written beforehand to the non-volatile memory 13. This prevents the operation of the reconfigurable circuit 11 from being analyzed when a peeling analysis is conduced on the circuit 11. Thus, the semiconductor device 10 is difficult to reverse engineer.

(2) Among the signal wirings formed in the register 14 and reconfigurable circuit 11, the probe inhibiting wiring (the third-layer wiring 34c in this example) covers at least the signal wirings that transmit signals significant for analysis (in this example, the second-layer wirings 33a and 33b). This prevents the value of the register 14 in an active state from being analyzed through signal analysis using a mechanical probe or an electronic probe. As a result, even if the structure of the reconfigurable circuit 11 is analyzed by conducting a peeling analysis, the analysis of the circuit operation is prevented since the register value subsequent to data loading cannot be known. Thus, the semiconductor device 10 is difficult to reverse engineer.

(3) The third-layer wiring 34c, which covers the second-layer wirings 33a and 33b transmitting signals significant for analysis, is formed by a wiring in the same layer (in this example, the uppermost layer wiring) as the power supply wirings (in this example, the third-layer wirings 34a and 34b). Accordingly, if the third-layer wiring 34c is removed for performing signal analysis on the second-layer wirings 33a and 33b, the third-layer wirings 34a and 34b are also removed. This breaks the power supply line. Consequently, the semiconductor device 10 becomes further difficult to reverse engineer.

(4) The confidentiality of encryption information used in an authentication system is significantly improved by applying the semiconductor device 10 of the present embodiment to, for example, the ID generators (first and second LSIs 44 and 45) that generate identification signals in the authentication system 40 to authenticate the battery pack 42 attached to the portable device 41. Therefore, identification signals may be generated with an undisclosed and relatively simple algorithm. This provides a system having a high level of confidentiality at a low cost.

It should be apparent to those skilled in the art that the present invention may be embodied in many other specific forms without departing from the spirit or scope of the invention. Particularly, it should be understood that the invention may be embodied in the following forms.

The probe inhibiting wiring (third-layer wiring 34c) may be formed by a semiconductor device having a multilayer wiring structure other than the three-layer wiring structure.

In the preferred embodiment, the probe inhibiting wiring (third-layer wiring 34c) is formed to entirely cover wiring patterns in lower layers of the inverter circuit. However, the probe inhibiting wiring is only required to cover the signal wirings that are significant during analysis (for example, the second-layer wirings 33a and 33b).

The semiconductor device 10 provided with the reconfigurable circuit 11 may be embodied in devices other than the ID generators (first and second LSIs 44 and 45).

Therefore, the present examples and embodiments are to be considered as illustrative and not restrictive and the invention is not to be limited to the details given herein, but may be modified within the scope and equivalence of the appended claims.

1. A semiconductor device comprising:
a reconfigurable circuit having a circuit configuration that is switchable in accordance with circuit operation setting data;
a non-volatile memory for storing the circuit operation setting data; and
a register, connected to the non-volatile memory and the reconfigurable circuit, for receiving the circuit operation setting data when read from the non-volatile memory and providing the circuit operation setting data to the reconfigurable circuit.

2. The semiconductor device according to claim 1, wherein the reconfigurable circuit includes a plurality of reconfigurable cells, each of which sets a logic combination in accordance with the circuit operation setting data.

3. The semiconductor device according to claim 1, wherein the circuit operation setting data is loaded from the non-volatile memory into the register when the semiconductor device is activated.

4. The semiconductor device according to claim 1, further comprising:
a power-on boot circuit, connected to the non-volatile memory and the register, for loading the circuit operation setting data from the non-volatile memory into the register when the semiconductor device is activated.

5. The semiconductor device according to claim 1, further comprising:
a plurality of signal wirings connected to the register; and
a probe inhibiting wiring covering, among the plurality of signal wirings, at least a signal wiring that transmits a signal significant for analysis of a value of the register.

6. The semiconductor device according to claim 5, wherein the signal wiring that transmits a signal significant for analysis of the register value is one of two signal wirings respectively transmitting an input signal and an output signal of the register.

7. The semiconductor device according to claim 5, further comprising:
a power supply wiring, with the probe inhibiting wiring being formed in the same layer as the power supply wiring.

8. A semiconductor device comprising:
a plurality of signal wirings formed in a plurality of layers, respectively; and
a probe inhibiting wiring covering, among the plurality of signal wirings, at least a signal wiring that transmits a signal significant for analysis of operation of the semiconductor device.

9. The semiconductor device according to claim 8, further comprising:
a power supply wiring, with the probe inhibiting wiring being formed in the same layer as the power supply wiring.

10. The semiconductor device according to claim 8, further comprising:
a functional circuit connected to the plurality of signal wirings, wherein the signal wiring that transmits a signal significant for analysis of operation of the semiconductor device is one of two signal wirings, which respectively transmit an input and an output signal for the functional circuit.

11. The semiconductor device according to claim 10, wherein the functional circuit is a register.

12. An ID generator, configured as a semiconductor device, for generating an identification signal required to authenticate an external device attached to a main device, the ID generator comprising:
a reconfigurable circuit configured to dynamically respond to circuit operation setting data and generate an identification signal in accordance with predetermined encryption processing;
a non-volatile memory for storing the circuit operation setting data; and
a register, connected to the non-volatile memory and the reconfigurable circuit, for receiving the circuit operation setting data when read from the non-volatile memory and providing the circuit operation setting data to the reconfigurable circuit.

13. The ID generator according to claim 12, wherein the reconfigurable circuit includes a plurality of reconfigurable cells, each of which sets a logic combination in accordance with the circuit operation setting data.

14. The ID generator according to claim 12, wherein the circuit operation setting data is loaded from the non-volatile memory into the register when the ID generator is activated.

15. The ID generator according to claim 12, further comprising:
a power-on boot circuit, connected to the non-volatile memory and the register, for loading the circuit operation setting data from the non-volatile memory into the register when the ID generator is activated.

16. The ID generator according to claim 12, further comprising:
a plurality of signal wirings connected to the register; and
a probe inhibiting wiring covering, among the plurality of signal wirings, at least a signal wiring that transmits a signal significant for analysis of a value of the register.

17. The ID generator according to claim 16, wherein the signal wiring that transmits a signal significant for analysis of the register value is one of two signal wirings, which respectively transmit an input signal and an output signal for the register.

18. The ID generator according to claim 16, further comprising a power supply wiring, with the probe inhibiting wiring being formed in the same layer as the power supply wiring.
